(19) United States
(12) Patent Application Publication
(10) Pub. No.: US 2015/0084649 A1
(43) Pub. Date: Mar. 26, 2015

(54) CAPACITIVE WIRE SENSING FOR GUARDING APPLICATIONS

(71) Applicant: L & P PROPERTY MANAGEMENT COMPANY, South Gate, CA (US)

(72) Inventors: RYAN E. CHACON, CARTHAGE, MO (US); JASON B. TURNER, JOPLIN, MO (US); JASON A. WYNNE, PARK RIDGE, IL (US)

(21) Appl. No.: 14/496,997

(22) Filed: Sep. 25, 2014

Related U.S. Application Data
(60) Provisional application No. 61/882,744, filed on Sep. 26, 2013.

(51) Int. Cl. G01N 27/22; G07C 9/00; G01R 35/00; G01R 27/26; G01B 7/14

(52) U.S. Cl. CPC G01N 27/22; G01R 27/2605; G01B 7/14; G01R 35/00; G07C 9/00111
USPC 324/658

(57) ABSTRACT

A system, method and device for capacitive sensing of a guarding application is provided. A capacitive sensing module is coupled to one or more features of a guard system having capacitive guard panels and protective grids. Based on a user contacting at least a portion of the guard system, a determined indication of contact and/or presence may trigger a corresponding response by the guard system via the capacitive sensing module. A baseline level of noise is calibrated over time to adjust for varying conditions that do not correspond to a triggered, user-detection measurement. Corresponding outputs are generated based on a type of detection information received and/or user identity associated with the received capacitance detection. A capacitive sensing module may be configured to receive one or more items of capacitance change data and determine an appropriate triggered response based on an amount of capacitance change and threshold detection duration.

### CROSS-REFERENCE TO RELATED APPLICATIONS

This application claims priority to U.S. Provisional Application No. 61/882,744, filed Sep. 26, 2013, entitled “Capacitive Wire Sensing for Guarding Applications,” having attorney docket number LGPL.195619, the entire disclosure of which is hereby incorporated by reference.

### TECHNICAL FIELD

The present invention generally relates to presence-sensing technology incorporated into guards and fencing. More particularly, the invention relates to incorporating a capacitance sensing system into a guard or fence for detecting the contact or presence of a person.

### BACKGROUND OF THE INVENTION

It may be useful to detect the presence of a person coming into contact with a guard or fencing type material. Upon detection of a triggering event, such as contact, a variety of preprogrammed responses may be initiated. A need exists for a reliable presence-sensing technology for use with guarding and fencing type applications.

### BRIEF SUMMARY OF THE INVENTION

The present invention generally relates to an apparatus for presence detection that incorporates a capacitive component into guards and or protective fencing. It should be understood that the invention contemplates incorporating a capacitive sensing device into a variety of items used for the protection of equipment or others, and that the invention is not limited to the specific item for which presence detection is provided. Additionally, the present invention is described as detecting/sensing the presence of a person or other being using exemplary components such as a low voltage power source and a processor within a capacitance sensing device. Although a final determination of presence may be conducted using a processor and/or software associated with the claimed apparatus, reference to sensing and/or detection “by” any portion of the guard, or a determination thereof by the processor, is not meant to be limiting. For example, a conductive signal detected by contact with a guard may be processed by software associated with a processor, and such processing may result in a final determination of presence or contact. In other words, a conductive frame or guard could be described as having “detected” presence, even though the detection determination was ultimately made in software associated with a processor.

In one embodiment, a capacitive component is secured to a portion of a guard. For example, a low voltage source may be secured to a perimeter of a guard. In a further embodiment, capacitive wiring is integrated into the frame supporting the guard. In further embodiments, a metal frame may be pulsed with a charge and used to monitor a change in capacitance based on contact with the metal frame. Software associated with the low voltage source and the capacitive wires/grids/metal frames may then make a determination of presence and/or contact of a body with respect to a guard. Based on a determination of contact or lack thereof, a corresponding output function, feature, indicator, and/or response may be activated.

In another illustrative aspect, the present invention includes a method for detecting presence with respect to a guard. The method includes receiving information provided by at least one capacitive component coupled to a perimeter of the guard, wherein the capacitive component is adapted to have a voltage based on the proximity of an object to the capacitive component; determining that a change in voltage satisfies a threshold amount; and based on determining that the threshold amount is satisfied, initiating a corresponding response.

In another embodiment, a method for detecting presence with respect to a guard comprises: receiving information provided by at least one capacitive component coupled to the guard, wherein the at least one capacitive component comprises a metal frame, wherein receiving information comprises providing the metal frame with a voltage to provide a charge to the metal frame, and determining that a change in voltage satisfies a threshold, wherein determining that a change in voltage satisfies a threshold comprises: (1) monitoring a change in voltage detected by the at least one capacitive component over a particular period of time; and (2) comparing the change in voltage over the period of time with the threshold.

In some aspects of the invention, a system and method are provided for incorporating presence-sensing technology into a capacitive guard device and/or storage locker. Based on coupling a capacitive sensing module to the guard device, a charge may be applied to the guard device, and the guard device may be monitored for a subsequent change in capacitance detection. In some aspects, the capacitive sensing module includes instructions, such as those embodied in software media discussed above, that adaptively measure and/or monitor the capacitance of the guard device. As such, a change in capacitance may be measured over time with respect to a baseline level of applied capacitance from the charge that the guard device is receiving. In one aspect, the capacitive sensing module may determine the detection of a human near the guard device, such as a human standing next to the guard device. In another aspect, the software associated with the capacitive sensing module (either directly coupled to the capacitive sensing module or remotely controlling the features of the capacitive sensing module from a remote computing device) may determine if the detected presence satisfies a threshold level of detection from either a proximity detection of user presence, or a detection of direct contact with the guard device. In one aspect, the capacitive sensing module is configured to detect a change in capacitance similar to the capacitive detection monitored and reacted to via a touchscreen device.

In one embodiment of the invention, a small voltage is applied to the guard device being monitored, such as a voltage within a minimal range required for detection and/or monitoring. The capacitive sensing module may receive information from the guard device (that is receiving the voltage), and determine when a change in such monitored voltage over time satisfies a threshold level of detection. As such, the capacitive sensing module may determine whether human contact and/or presence has been detected based on the received indication of change in monitored voltage. In one embodiment of the invention, a capacitive voltage divider (CVD) and/or a charge time measurement unit (CTMU) may be used to provide a detection algorithm for determination by the capacitive sensing module. In one aspect, a user may pre-set a sensitivity level and/or threshold requirement desired before triggering an indication of presence/contact. For example, an enclosure protecting a particular machine in a high-traffic area of a warehouse may experience multiple presence indications from users within a proximity of a guard device, but the sensitivity of the guard device may be set to only trigger a corresponding response when a stronger change in capacitance is detected, such as actual contact with the guard device.

Based on a determination of presence/contact, or lack of presence/contact, a variety of corresponding features may be triggered by the capacitive sensing module, according to embodiments of the invention. For example, an alarm may be activated, a surveillance camera may be triggered, a message may be sent to a mobile device, a message may be sent to a remote computing device, and the like. By triggering such alerts/notifications, a first user may be notified that a second user is attempting to open a guard device enclosing a protected area. In further aspects, an alert/notification may provide an indication of one of multiple different types of contact with the guard device, such as a determination that a user is trying to climb or circumvent the guard device. In another aspect, an alert may be triggered that corresponds to a particular item enclosed within a guard device. For example, an alert may be triggered that a user is attempting to use a machine enclosed within a guard device, with a portion of the guard not in place (e.g., the guard may be left partially open, and an alert is triggered to notify the user that the machine may not be operated while the guard gate is open).

Additional objects, advantages, and novel features of the invention will be set forth in part in the description which follows, and in part will become apparent to those skilled in the art upon examination of the following, or may be learned by practice of the invention.

### BRIEF DESCRIPTION OF SEVERAL VIEWS OF THE DRAWING

The present invention is described in detail below with reference to the attached drawing figures, wherein:

FIG. 1 is a perspective view of a representative guard, in accordance with embodiments of the invention;

FIG. 2 is an enlarged, perspective view of a portion of the guard of FIG. 1, in accordance with embodiments of the invention;

FIG. 3 is an enlarged, perspective view of a portion of the guard of FIG. 1, in accordance with embodiments of the invention;

FIG. 4 is a top perspective view of an assembled guard system, in accordance with embodiments of the invention;

FIG. 5A is a perspective view of components of a guard system, in accordance with embodiments of the invention;

FIG. 5B is a perspective view of components of a guard system, in accordance with embodiments of the invention;

FIG. 6 is a flow diagram of an exemplary method for detection using a guard, in accordance with embodiments of the invention;

FIG. 7 is an exemplary graphical display of the measure of contact detection with a guard using capacitance monitoring, in accordance with embodiments of the invention;

FIG. 8 is an exemplary computing device for use during capacitance monitoring, in accordance with embodiments of the invention;

FIG. 9 is an exemplary network diagram for accessing data from a capacitive sensing module, in accordance with embodiments of the invention;

FIG. 10 is an exemplary network environment for accessing data from a capacitive sensing module, in accordance with embodiments of the invention;

FIG. 11 is a flow diagram of an exemplary method for detection using a guard, in accordance with embodiments of the invention; and

FIG. 12 is an exemplary graphical display of the measure of contact detection with a guard using capacitance monitoring, in accordance with embodiments of the invention.

### DETAILED DESCRIPTION OF THE INVENTION

Embodiments of the invention relate to incorporating a capacitance sensing system into a guard or fence for detecting the contact and/or presence of a person. In some aspects of the invention, a method for detecting presence with respect to a guard is provided. The method includes: receiving information provided by at least one capacitive component associated with the guard; determining that a change in voltage satisfies a threshold amount; and based on determining that the threshold amount is satisfied, initiating a corresponding response.

In another embodiment of the invention, a guard system for restricting access to an internal area using capacitance detection is provided. The guard system includes: a plurality of guards coupled to a plurality of vertical posts; and a capacitive sensing module coupled to the plurality of guards, wherein the capacitive sensing module comprises: (1) a charge component, (2) a monitoring component, and (3) a detection component.

In a further aspect, a capacitive guard device for monitoring and restricting user access is provided. The capacitive guard device includes a capacitive guard comprising: (1) a plurality of guard panels, each of the plurality of guard panels comprising a capacitive material, and (2) a plurality of vertical posts coupled to the plurality of guard panels, wherein each of the plurality of vertical posts comprises a capacitive material; and further wherein each of the plurality of vertical posts is coupled to at least one of the plurality of guard panels along a vertical axis of the plurality of guard panels to provide an enclosed space within the capacitive guard that is inaccessible by a user adjacent the vertical axis. Additionally, the capacitive guard device includes a capacitive sensing module coupled to at least a portion of one or more of the plurality of guard panels and the plurality of vertical posts, the capacitive sensing module comprising one or more of the following: (1) a charge component; (2) a monitoring component; (3) a detection component; (4) a charge component; (5) a monitoring component; (6) a detection component; (7) a calibrating component; (8) a communication component; (9) a power source; (10) an alerting component; (11) an authentication component; and (12) a database.

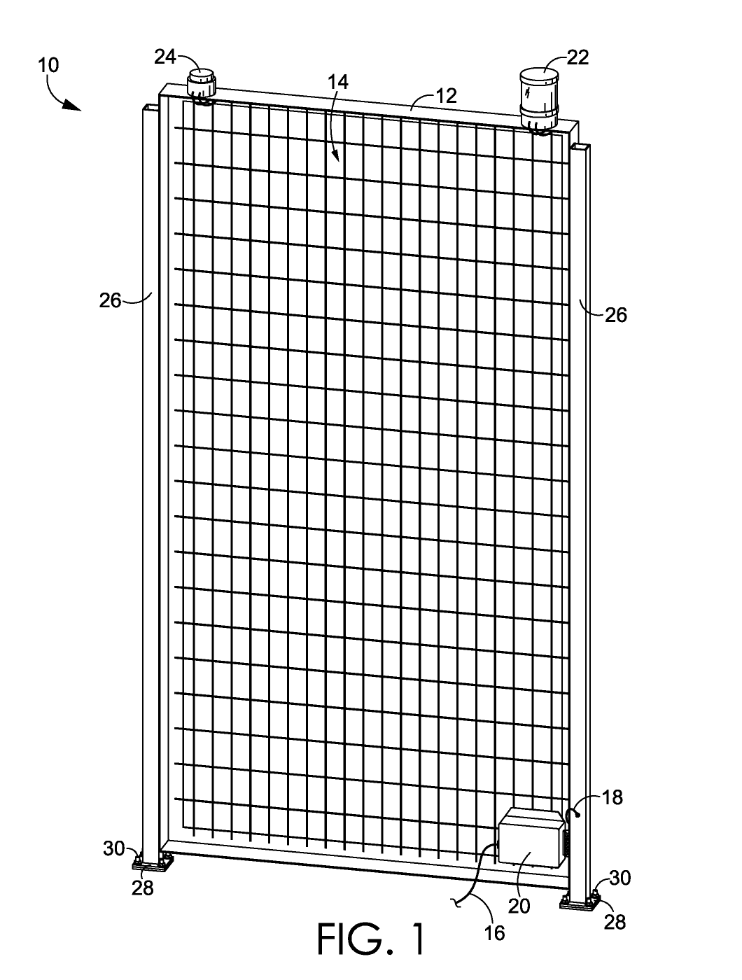

With reference now to the figures, FIG. 1 illustrates a representative guard 10 that can be used in a variety of applications. Guard 10 has an outer frame 12 that supports a protective grid 14. The frame 12 is typically formed from a steel material, but can be formed from other materials as well, such as other metallic and/or conductive materials configured to carry a charge. Similarly, the protective grid 14 is typically a metal grid, but may be made from another metallic and/or conductive material, according to some embodiments. The guard 10 shown in the figures is one possible configuration, but it should be understood that other configurations, shapes, etc., could be implemented depending on the particular guarding application. Moreover, the inventive concepts disclosed herein could be applied to many other applications, such as storage lockers, bins, etc.

Guard 10 also includes a power source 16 that provides low voltage power output to lead 18. The power source 16 may be any power source configured to generate a charge for applying to the guard 10. In some aspects, the power source 16 is an electrical wall outlet to which the guard 10 is coupled, while in other embodiments, the power source 16 is solar powered. In further aspects, the power source 16 includes a primary power source and a secondary power source, such as a primary coupling to an electrical outlet, and a secondary backup battery power source. In some embodiments, the power source 16 includes a surge protection device configured to protect one or more features of the power source 16, and ensure the continued power supply to the capacitive sensing module during monitoring. As shown in the example of FIG. 1, a lead 18 is coupled to the frame 12, such that a low voltage is applied to the frame 12 and the grid 14. In some aspects, the lead 18 includes a single connection, while in further aspects, the lead 18 includes multiple connections to the frame 12 and/or grid 14.

The lead 18 is also used to feed information to capacitive sensing module 20. In some embodiments of the invention, the capacitive sensing module 20 includes one or more components for providing a charge to the frame 12 and/or grid 14, one or more components for monitoring a change in capacitance with respect to the frame 12 and/or grid 14, and one or more components configured to determine a corresponding output in response to the monitored detection. The capacitance measured across the frame 12 may be monitored by a processor in the capacitive sensing module 20 that uses software to generate a determination of contact or presence detection. In one embodiment, the Microchip® brand capacitive sensor may be used to determine when presence is detected. As such, while presence detection relies on the contact of a person or body with respect to the guard, a determination of the level of detection and/or the measurement of presence is conducted digitally, in software associated with one or more processors. In some aspects, as discussed below, the processor(s) used to determine a level of detection and/or the measurement of presence, and to initiate the corresponding response by the capacitance sensing module 20, may be located within the capacitance sensing module 20. Additionally, in further embodiments, a remote processor may be coupled to the capacitance sensing module 20 for determining a level of detection and/or the measurement of presence.

In some embodiments of the invention, the capacitive sensing module 20 is used to detect the presence and/or contact of a person or other being with a guard 10, including a series of multiple guards 10 coupled together (e.g., a series of outer frames 12 and protective grids 14 coupled together). As will be understood, additional capacitive components (e.g., additional components configured to have and/or carry a charge), such as additional capacitive wire segments or leads, may be coupled to the outer frame 12, the protective grid 14, and/or the vertical post 26. In further embodiments, wire segments may surround the frame, rather than attaching the leads 18 to the frame itself, to provide a charge and/or enable the capacitive monitoring of a charge applied to the grid 14. In further embodiments, a capacitive sensing module 20 may be coupled to the guard 10 to both provide a minimal amount of charge to the guard 10 and to receive data corresponding to a change in capacitance.

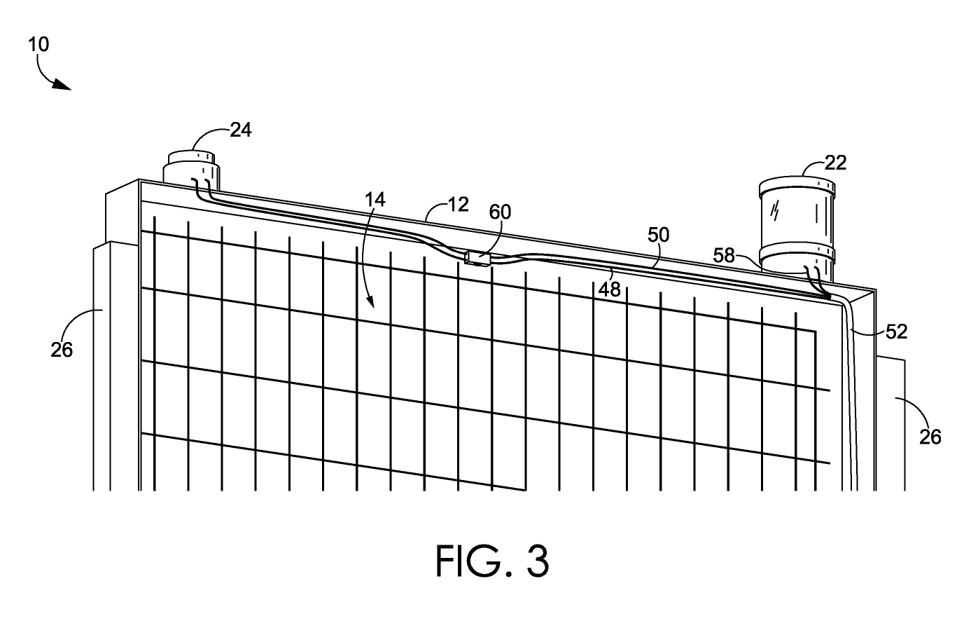

In embodiments, capacitive sensing module 20 is used to monitor a change in capacitance over a specified amount of time. The capacitive component (outer frame 12 and protective grid 14) is adapted to have a voltage supplied by power source 16. Such voltage information is collected via the capacitive component (the frame 12 and protective grid 14) and received by the processor in device 20, which determines when a change in capacitance or voltage satisfies a threshold. Once a particular change in capacitance satisfies a threshold, a corresponding outcome function is triggered. For example, the guard 10 may include a warning light 22 or audible alarm 24 that are triggered when capacitive sensing module 20 detects a change in capacitance over the predetermined threshold, as shown in FIGS. 1 and 3.

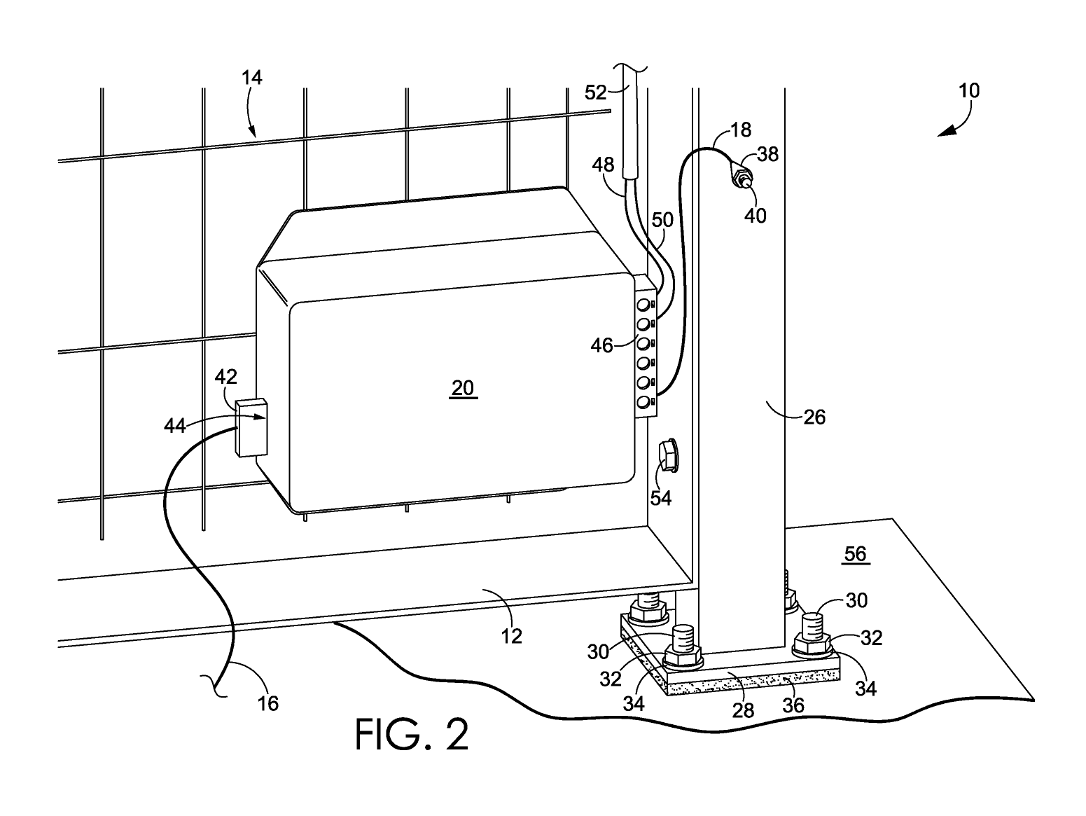

As further depicted in FIGS. 1-3, the exemplary guard 10 includes a pair of vertical posts 26 on each side of the outer frame 12. In embodiments, the vertical posts 26 are a conductive material configured to carry a charge applied to the guard 10. As such, a voltage applied to the capacitive component (the outer frame 12 and the protective grid 14) may be carried from one guard 10 to an adjacent guard 10 based on coupling between neighboring vertical posts 26 and/or between neighboring outer frames 12 coupled to a common vertical post 26. In the example of FIG. 1, each of the vertical posts 26 include a base plate 28 that may be secured to a surface, such as the ground or floor of a room, using bolts 30. In the enlarged view of FIG. 2, a non-conductive coaster 36 is adjacent the base plate 28 and is positioned between the base plate 28 and the ground surface 56. The non-conductive coaster 36 may be made from any material, or combination of materials, that does not carry a charge. For example, non-conductive coaster 36 may be an insulating material such as a plastic, rubber, cork, and/or other material.

FIG. 2 also includes further exemplary details of the bolts 30 used to secure the guard 10 to the ground surface 56. In one embodiment, the bolts 30 are coupled to the base plate 28 using nuts 32 and non-conductive washers 34. Non-conductive washers 34 may be made from any non-conductive material, or combination of materials, that does not carry a charge. As such, non-conductive washers 34 may be made from the same non-conductive material as the non-conductive coasters 36. In order to decouple the guard 10 from any charge carried by and/or transmitted from an external environment, the base plate 28 of each vertical post 26 is coupled to the ground surface 56 using tightening mechanisms that prevent and/or interrupt flow of a charge/voltage to or from the guard 10. For example, a bolt 30 and nut 32 may be made from a conductive material and may be used to couple the conductive vertical post 26 to the ground surface 56 without carrying a charge to or from the guard 10. As such, in some embodiments of the invention, the vertical posts 26 are separated from direct contact with the ground surface 56 based at least in part on a non-conductive coaster 36 and/or non-conductive washer 34, thereby providing a “floating” guard 10 system.

The guard 10 may further include any number of additional components coupled to the capacitive sensing module 20, such as the audible alarm 24. Multiple input/output (I/O) ports 46 may be provided in association with the capacitive sensing module 20, which may couple one or more leads to transmit information to and from the capacitive sensing module 20, such as leads 48 and 50, which are coupled to insulator 52 in the example of FIG. 2. One or more different types of I/O components may be coupled to the capacitive sensing module 20, and may be directly or indirectly coupled to the guard 10, or to a series of guards 10. For example, while warning light 22 and audible alarm 24 are shown coupled to a top edge of the outer frame 12, such features may be located in a different position, such as the warning light 22 being positioned on a ceiling surface above the ground surface 56, with a wireless connection (e.g., WiFi, zigbe, Bluetooth, etc.) between the warning light 22 and the capacitive sensing module 20. Similarly, a central warehouse control may include an audible alarm 24 that is coupled, either by wire or wirelessly, to the capacitive sensing module 20. In some aspects, one or more features for attaching a lead, such as leads 48, 50, and 58 of FIG. 3, may couple an accessory and/or external component to the guard 10, such as coupling mechanism 60 of FIG. 3.

With continued reference to FIG. 2, the guard 10 may include a conductive ring terminal 38 associated with the lead 18 that couples the capacitive sensing module 20 to the vertical post 26. The conductive ring terminal 38 may be coupled to any portion of a capacitive component of a guard system to provide a charge to and/or provide monitoring of the guard system. In one example, the conductive ring terminal 38 is directly coupled to the vertical post 26 using bolt 40, all of which features include a conductive/capacitive feature. Further, the vertical post 26 may be coupled to the outer frame 12 of the guard 10 using a capacitive coupling mechanism, such as the bolt 54. Based on the coupling of such capacitive features, the power source 16 may provide power to the capacitive sensing module 20 via the power plug 42 coupled to I/O port 44, which enables a charging component of the capacitive sensing module 20 to provide a charge to the guard 10 systems via lead 18 and conductive ring terminal 38.

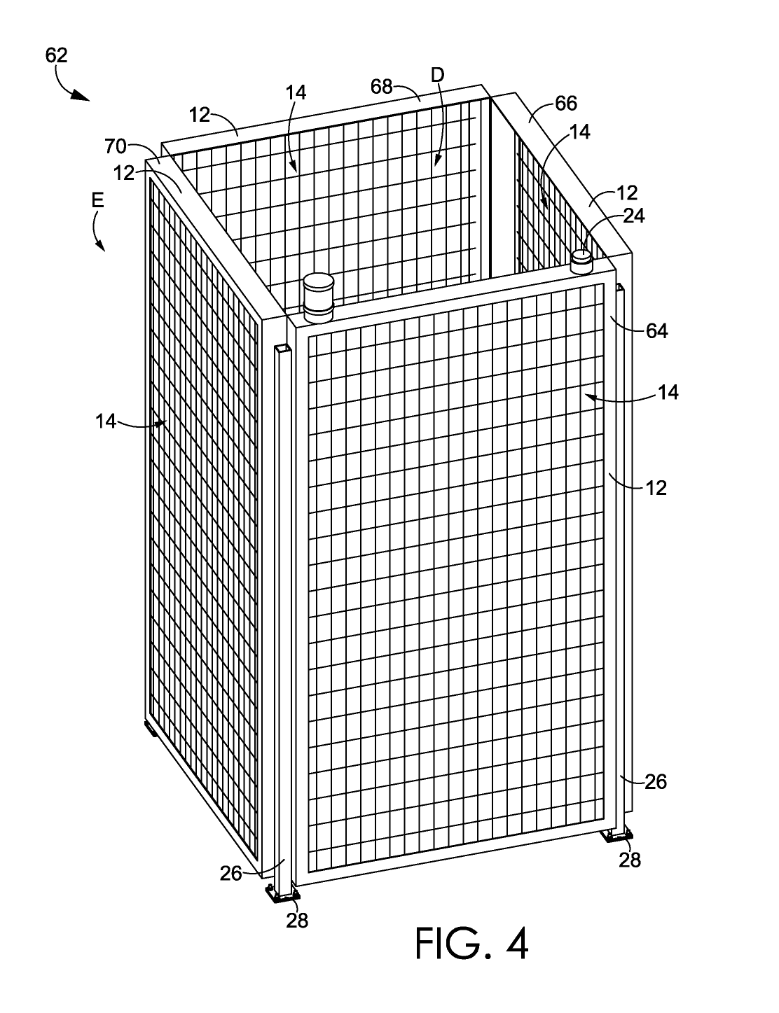

With reference to FIG. 4, an exemplary assembled guard system 62 includes a first guard panel 64, a second guard panel 66, a third guard panel 68, and a fourth guard panel 70. Based on coupling together for the first, second, third, and fourth guard panels 64, 66, 68, and 70, a guarded internal area D is separated from an unguarded area E shown in FIG. 4. As such, the assembled guard system 62 may be used to restrict access to one or more items stored within the guarded internal area D. While the example of FIG. 4 depicts four guard panels in a series, joined to shared vertical posts 26 at each corner, embodiments of an assembled guard system 62 may include a different number of guard panels to provide an enclosed area, in a variety of different configurations and/or layouts. As will be discussed in more detail below, capacitance monitoring of the assembled guard system 62 may provide an indication that the internal area D has been accessed and/or the protection provided by the adjacent guard panels has been interrupted.

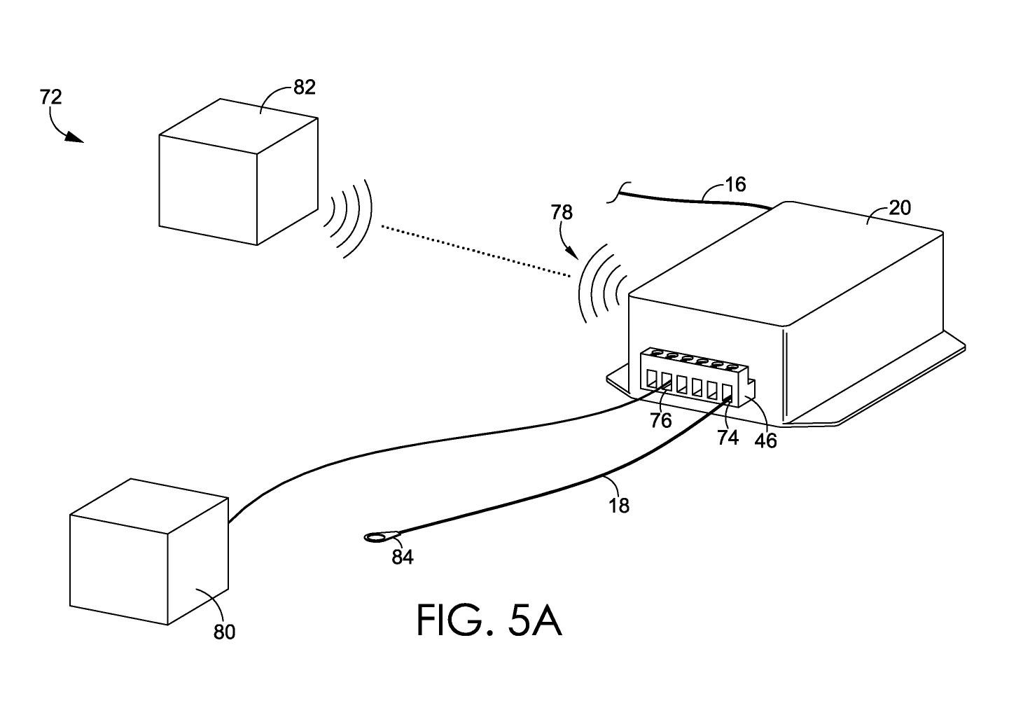

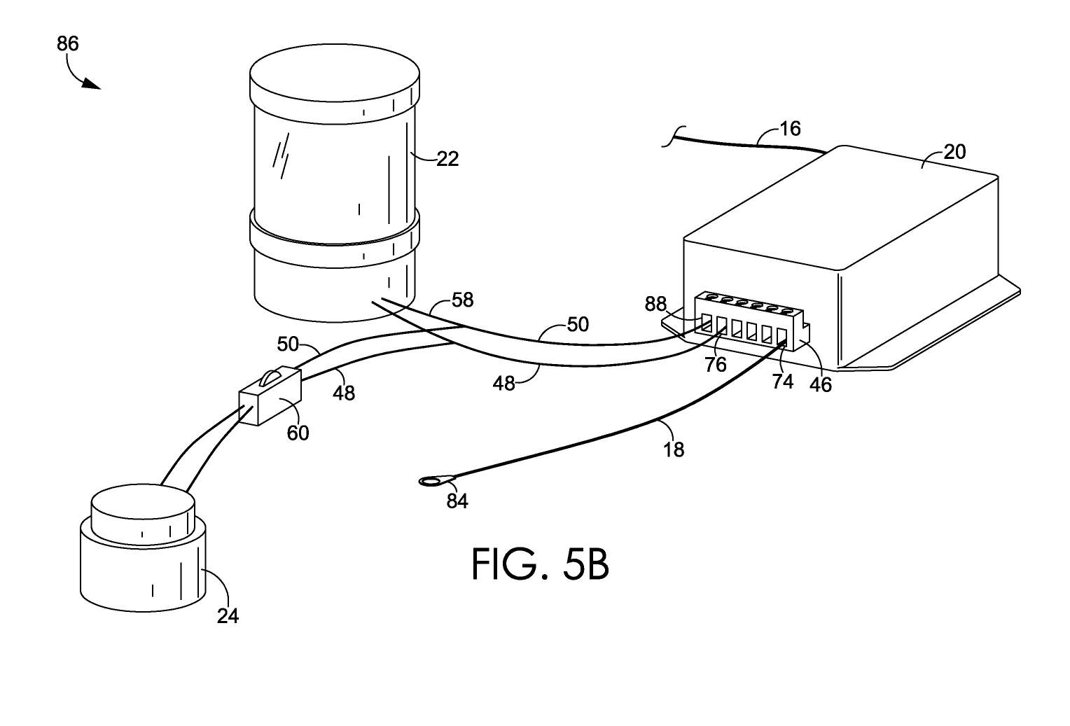

In the example of FIG. 5A, an exemplary capacitive sensing module configuration 72 includes a capacitive sensing module 20, a first I/O port 74, a second I/O port 76, a wireless connection 78, a first external component 80, a second external component 82, and a ring terminal 84. In some aspects, a capacitive sensing module 20 may be coupled to a capacitive component (e.g., the assembled guard system 62) via I/O port 74, lead 18, and ring terminal 84, thereby enabling a charge to be applied to the capacitive component from the capacitive sensing module 20. Further, in response to the applied charge transmitted via lead 18 and ring terminal 84, one or more responses may be elicited by the capacitive sensing module 20, such as a directly coupled first external component 80, or a wirelessly coupled second external component 82. In the exemplary capacitive sensing module configuration 86 of FIG. 5B, the third I/O port 88 and the second I/O port 76 may be used to couple the capacitive sensing module 20 to the warning light 22 and the audible alert 24 via leads 48, 50, and 58. The multiple I/O ports 46 may be used to couple any number of additional or alternative external components to the capacitive sensing module 20, which may be used to trigger a particular output based on the detected change in capacitance. In further embodiments, the external components such as the warning light 22 and the audible alert 24 may include an air horn, a buzzer, a building alarm, a remote alarm, or any other alerting and/or notification device coupling of the capacitive sensing module 20. In some aspects, while the warning light 22 and the audible alert 24 are depicted in FIG. 5B as being directly coupled to the capacitive sensing module 20 based on leads 48, 50, and 58, a connection between an external component and the capacitive sensing module 20 may be wireless, and may be communicated directly or indirectly to one or more external components, such as a remote computer, a remote cellular device, a remote control center, and the like.

A variety of communication protocols may be used to control the variety of functions described above. For example, a two-way controller using a ZigBee® wireless communication protocol may be used. In some embodiments, a two-way communication protocol intended for use in automation (similar to Bluetooth®) may be utilized. In another embodiment, two separate microcontrollers may be used: one dedicated primarily for sensing purposes that, when it detects something, sends a signal to a secondary device/microcontroller that is programmed to initiate the corresponding response.

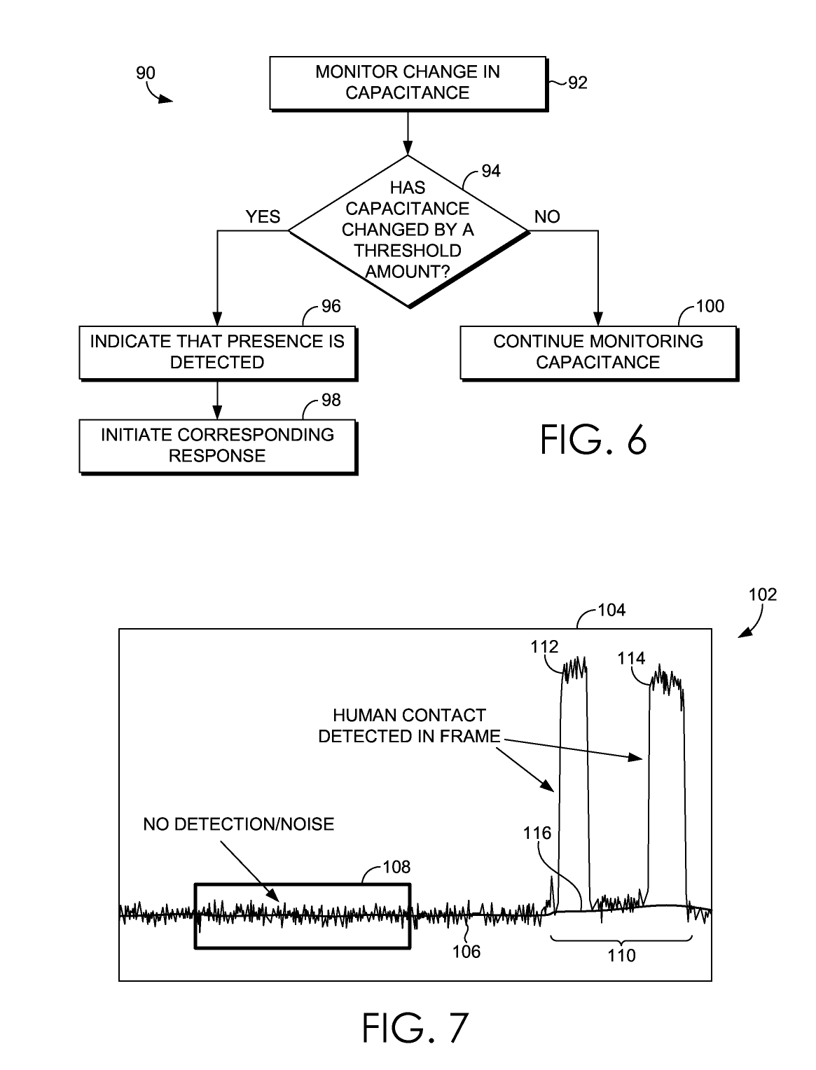

Turning now to FIG. 6 an exemplary flow diagram 90 for monitoring capacitance using a capacitive sensing module 20 of a guard 10 is provided. In some aspects of the invention, a change in capacitance detected by the capacitive sensing module 20 is monitored over time. Based on satisfying a particular threshold change in capacitance, various other output functions and/or corresponding responses associated with the guard 10 system may be activated and/or enabled. As another example, a machine or operation may be disabled as an output function and/or corresponding response. Many other output functions may be implemented as well. In other words, capacitive sensing module 20 may initiate a variety of functions based on received data indicating contact or lack of contact, as determined using capacitance information. In one example, after contact is no longer detected in the guard 10 system, the machine or device may be allowed to restart.

As shown in FIG. 6, the exemplary flow diagram 90 depicts monitoring capacitance and making a determination of presence, as shown in first block 92. A change in capacitance with respect to a guard 10 is monitored, such as by applying a charge to a capacitive component and monitoring the change in capacitance carried by the capacitive component, by the capacitive sensing module 20. At block 94, a determination is made as to whether a change in capacitance has satisfied a threshold amount. As discussed above, the change in capacitance indicates a change in voltage over a particular amount of time. At block 94, a determination is made regarding whether the capacitance has changed by a threshold amount. If a determination is made that the capacitance has changed by a threshold amount (i.e., a particular amount of change in voltage has occurred within a particular window of time), then an indication is made that presence has been detected at block 96, and the corresponding response is initiated at block 98. As will be understood, blocks 96 and 98 may, in some embodiments, be combined into a single step of initiation of the corresponding response based on a determination of presence detection. At block 100, if capacitance has not changed by a threshold amount, capacitance monitoring continues.

With reference to FIG. 7, capacitance detection 102 is shown on a display 104 that includes monitoring of capacitance 106 of a guard system 62. Detection area 108 designates the indication of no contact being detected and also provides an indication of the inherent level of noise that is detected by the system. In some aspects, a guard system may adjust in response to a noise-based level of detection, such as area 108. Further, detection area 110 includes peaks 112 and 114 corresponding to changes in capacitance relative to a baseline capacitance 116, which indicate that human contact with the outer frame 12 or protective grid 14 has been detected. As discussed above, a threshold for detection may be determined, such that a minimal amount of contact, for a short period of time, may not trigger an indication of presence with respect to the frame. For example, a change in capacitance at or above a threshold change in capacitance relative to the baseline capacitance 116 may first require a threshold amount of capacitance change for a threshold amount of time before triggering a corresponding response. As stated above, detection of human contact with the frame, as indicated by peaks 112 and 114, may trigger a number of outputs, such as stopping of a machine, alerting of an alarm feature, or any combination of features programmed to activate in response to the appropriate trigger.

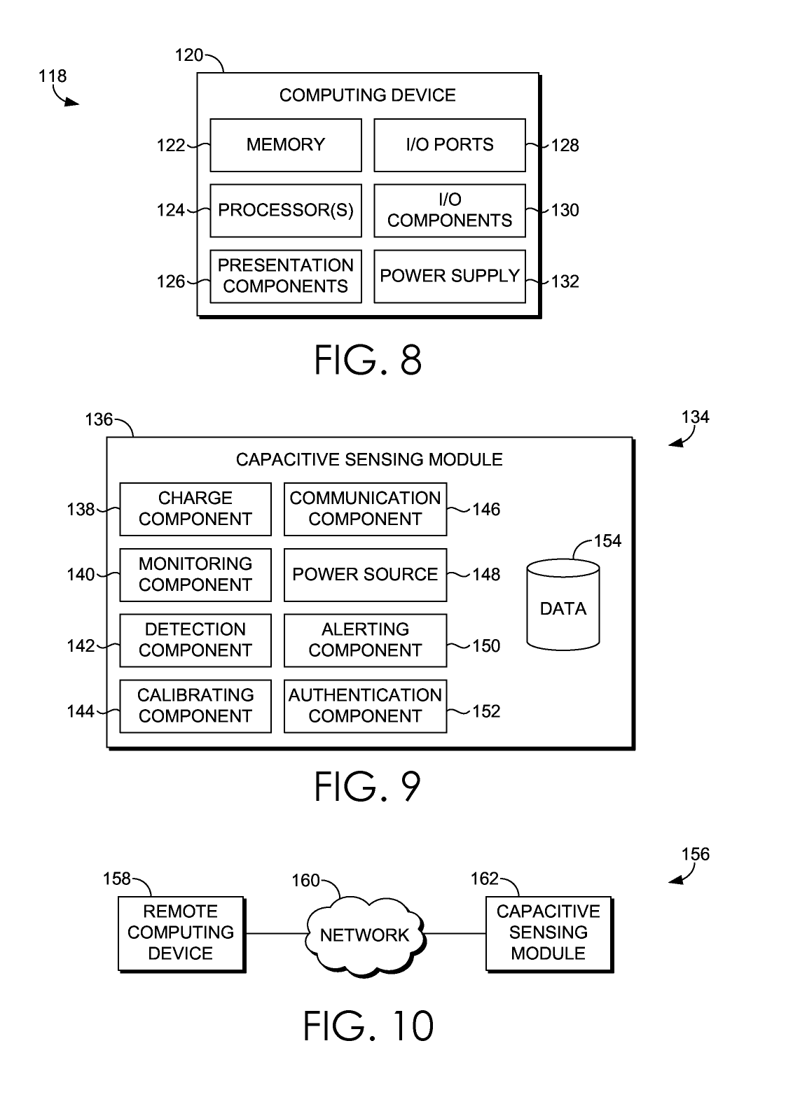

Referring now to FIG. 8, an exemplary component 118 of a guard system is provided, including exemplary features of a computing device 120, such as a memory 122, a processor 124, presentation components 126, I/O ports 128, I/O components 130, and a power supply 132. Computing device 120 is but one example of a suitable computing environment and is not intended to suggest any limitation as to the scope of use or functionality of embodiments of the invention. Neither should the computing device 120 be interpreted as having any dependency or requirement relating to any one component or any combination of components illustrated.

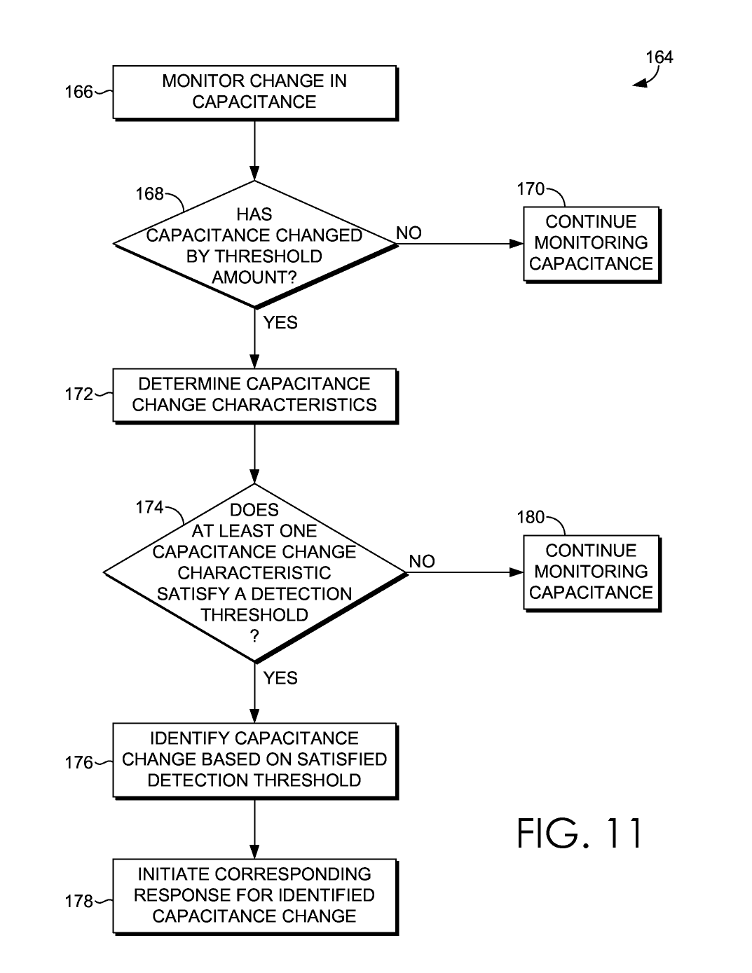

Embodiments of the invention may be described in the general context of computer code or machine-useable instructions, including computer-useable or computer-executable instructions such as program modules, being executed by a computer or other machine, such as a personal data assistant or other handheld device. Generally, program modules include routines, programs, objects, components, data structures, and the like, and/or refer to code that performs particular tasks or implements particular abstract data types. Embodiments of the invention may be practiced in a variety of system configurations, including handheld devices, consumer electronics, general-purpose computers, more specialty computing devices, and the like. Embodiments of the invention may also be practiced in distributed computing environments where tasks are performed by remote-processing devices that are linked through a communications network, such as the exemplary network environment 156 of FIG. 10 including a remote computing device 158, a network 160, and a capacitive sensing module 162.

With continued reference to FIG. 8, one or more of the following devices may be directly or indirectly coupled, in association with computing device 120, according to embodiments of the invention: memory 122, one or more processors 124, one or more presentation components 126, one or more input/output (I/O) ports 128, one or more I/O components 130, and an illustrative power supply 132. In embodiments, one or more busses may directly or indirectly couple one or more devices of the computing device 120. Although the various blocks of FIG. 8 are shown with borders for the sake of clarity, in reality, these blocks represent logical, not necessarily actual, components. For example, one may consider a presentation component such as a display device to be an I/O component. Also, processors have memory. The inventors hereof recognize that such is the nature of the art and reiterate that the diagram of FIG. 8 is merely illustrative of an exemplary computing device that can be used in connection with one or more embodiments of the present invention. Distinction is not made between such categories as “workstation,” “server,” “laptop,” “handheld device,” etc., as all are contemplated within the scope of FIG. 8 and reference to “computing device.”

The computing device 120 typically includes a variety of computer-readable media. Computer-readable media may be any available media that is accessible by the computing device 120 and includes both volatile and nonvolatile media, removable and non-removable media. Computer-readable media comprises computer storage media and communication media, computer storage media excluding signals per se. Computer storage media includes volatile and nonvolatile, removable and non-removable media implemented in any method or technology for storage of information such as computer-readable instructions, data structures, program modules, or other data. Computer storage media includes, but is not limited to, RAM, ROM, EEPROM, flash memory or other memory technology, CD-ROM, digital versatile disks (DVDs) or other optical disk storage, magnetic cassettes, magnetic tape, magnetic disk storage or other magnetic storage devices, or any other medium that can be used to store the desired information and that can be accessed by computing device 120.

Communication media, on the other hand, embodies computer-readable instructions, data structures, program modules, or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared, and other wireless media. Combinations of any of the above should also be included within the scope of computer-readable media.

The memory 122 includes computer storage media in the form of volatile and/or nonvolatile memory. The memory 122 may be removable, non-removable, or a combination thereof. Exemplary hardware devices include solid-state memory, hard drives, optical-disc drives, and the like. The computing device 120 includes one or more processors 124 that read data from various entities such as the memory 122 or the I/O components 130. The presentation component(s) 126 presents data indications to a user or other device. Exemplary presentation components 126 include a display device, speaker, printing component, vibrating component, and the like.

The I/O ports 128 allow the computing device 120 to be logically coupled to other devices including the I/O components 130, some of which may be built in. Illustrative I/O components include a microphone; joystick; game pad; satellite dish; scanner; printer; wireless device; a controller, such as a stylus, a keyboard, and a mouse; a natural user interface (NUI); and the like.

Aspects of the subject matter described herein may be described in the general context of computer-executable instructions, such as program modules, being executed by a computing device 120. Generally, program modules include routines, programs, objects, components, data structures, and so forth, which perform particular tasks or implement particular abstract data types. Aspects of the subject matter described herein may also be practiced in distributed computing environments where tasks are performed by remote-processing devices that are linked through a communications network, such as the network 160 of network environment 156 in FIG. 10. In a distributed computing environment, program modules may be located in both local and remote computer storage media including memory storage devices. The exemplary network environment 156 may include a database configured to provide storage of and/or access to one or more items of data via the network 160.

With reference to FIG. 9, an exemplary guard system component 134 for implementing embodiments of the present invention is shown. The guard system component 134 includes a capacitive sensing module 136 having a charge component 138, a monitoring component 140, a detection component 142, a calibrating component 144, a communication component 146, a power source 148, an alerting component 150, an authentication component 152, and a database 154. It will be understood by those of ordinary skill in the art that the components and/or modules illustrated in FIG. 9 are exemplary in nature and in number, and should not be construed as limiting. Any number of components and/or modules may be employed to achieve the functionality described herein. For example, any number of computing devices 120/158, capacitive sensing modules 136/162, and/or networks 160 may be employed by a guard system utilizing capacitive detection, within the scope of embodiments hereof. Further, components and/or modules may be located on any number of computing devices 120/158. Each component and/or module may comprise a single device and/or interface or multiple devices and/or interfaces cooperating in a distributed environment. Further, multiple components and/or modules may include the various components of the capacitive sensing module 136 that collectively perform the tasks of embodiments of the invention. For example, multiple devices arranged in a distributed environment may collectively provide the charging, monitoring, detecting, calibrating, communicating, powering, alerting, authenticating, and/or storing functionality of a capacitive sensing module described herein. By way of example, the detection component 142, features may be provided on a single server, a cluster of servers, or a computing device, such as the computing device 120, remote from one or more of the remaining components of the capacitive sensing module. In some instances, the detection component 142 or at least a portion of components included therein, is provided at the computing device 120. Other components and/or modules not shown may also be included within the guard system component 134.

In some embodiments, one or more of the illustrated components and/or modules may be implemented as stand-alone applications. In further embodiments, one or more of the illustrated components and/or modules may be implemented via a computing device (e.g., the computing device 120), as an Internet-based service, and/or as a module within the capacitive sensing module 136. The phrase “application” or “service” as used herein may broadly refer to any software, or portions of software, that runs on top of or accesses storage locations within a computing device 120 and/or multiple computing devices 120.

It should be understood that this and other arrangements described herein are set forth only as examples. Other arrangements and elements (e.g., machines, interfaces, functions, orders, and/or groupings of functions) can be used in addition to, or instead of, those shown, and some elements may be omitted altogether. Further, many of the elements described herein are functional entities that may be implemented as discrete or distributed components or in conjunction with other components, and in any suitable combination and location. Various functions described herein as being performed by one or more entities may be carried out by hardware, firmware, and/or software. For instance, various functions, including the functions described below with respect to the capacitive sensing module 136, may be carried out by a processor executing instructions stored in memory.

In some embodiments of the invention, a charge component 138 is configured to provide a charge to a capacitive component, such as a conductive outer frame 12 and/or protective grid 14. The charge provided by charge component 138 may be any amount of charge required to provide a minimum amount of detectable change in capacitance with respect to an assembled guard system. As such, the charge component 138 may apply a particular amount of charge based on power received from an electrical power source, a battery power source, and/or other source required to provide a low voltage charge to the conductive components of a guard system, in accordance with embodiments of the invention. The charge component 138 may also be configured to change an amount of charge applied to a capacitive component over a particular period of time. For example, charge component 138 may apply charge to a capacitive guard system at a first threshold level, and in response to a change in a baseline level of background noise and/or a change in strength of applied charge with respect to the capacitive features of the guard system, the charge component 138 may provide more or less charge to the guard system to maintain a threshold amount of charge needed to enable detection.

Monitoring component 140 may be referred to as a receiving and/or measuring component that monitors an applied level of capacitive charge, as provided by the charge component 138. In some aspects, the monitoring component 140 monitors a change in capacitance over time, with respect to a baseline level of applied charge to a capacitive component. The change in capacitance monitored may be assessed by the detection component 142 based on one or more criteria of the guard system. For example, a minimal change in capacitance with respect to a threshold level of expected and/or applied capacitance may be interpreted and/or identified by the detection component 142 as not indicating presence with respect to the guard system 62. In that example, the minimal change in charge not indicating presence may be associated with a person temporarily coming into contact with the guard system 62. As such, the detection component 142 may be used to prevent “false positive” results indicating that a temporary user presence is detected, but the content of the guarded internal area D (discussed above with respect to FIG. 4) remains intact.

In some embodiments of the invention, the detection component 142 may be used to adjust to a particular environmental condition that interferes with the capacitance monitoring by monitoring component 140 and interrupts an accurate correlation between change in capacitance and determined presence. In one example, a guard system utilized in a warehouse may have a forklift moved next to the structure, which may interrupt the baseline level of capacitance detection by the capacitive sensing module 136. As such, the detection component 142 may shift from a first level of detection to a second level of detection to compensate for the altered detection capabilities due to the presence of the forklift. In some aspects, a baseline for capacitance detection may be determined, and may be re-evaluated over time to account for a variety of external conditions during continued capacitance monitoring. As such, the detection component 142 may be configured as an adapting detection component 142.

As will be understood, the calibrating component 144 may utilize a variety of filtering techniques to adjust the determinations made (regarding whether presence is or is not detected) using software associated with the processor. For example, a variety of filters or transforms may be applied to the monitored capacitance signal to adjust and/or adapt the software for a particular application or user. As such, a processor may be trained to alter the sensitivity of a threshold based on previous use by a particular user of a corresponding feature. Additionally, a reaction time may be changed and a threshold may be adjusted for different functions. In one embodiment of the invention, the calibrating component 144 may be used to configure a particular capacitive sensing module to a particular user's specifications. As such, a manufacturer may provide a guard system having a set of predetermined thresholds for capacitive detection. Upon installation, an end user may then utilize features of the calibrating component 144 to adjust particular features of the system for use when monitoring capacitance change associated with the installed guarding device. In some embodiments of the invention, the capacitive sensing module may reconfigurable to utilize in one of multiple different guard settings, such as a first capacitive component of a first guard enclosure, and a second capacitive component of a second guard enclosure.

The capacitive sensing module 136 may include a communication component 146, such as a wired and/or wireless communication device configured to communicate at least one item of information to a recipient. For example, the communication component 146 may wirelessly provide a signal to a component coupled to the capacitive sensing module 136, such as the wireless connection 78 between the second external component 82 and the capacitive sensing module 120 shown in the example of FIG. 5A. In another aspect, a communication component 146 may include one or more wired features coupled one or more other devices for providing communicated information and/or data to or from the capacitive sensing module 136. The communication component 146 may be used to provide information to a remote computing device 120 from one or more components and/or features of the capacitive sensing module 136, such as communicating monitoring data from the monitoring component 140 to a remote computing device (e.g., a warehouse manager's computer).

The power source 148 feature of the capacitive sensing module 136, as discussed with reference to the power source 16 in FIG. 1, may provide power to one or more components of the capacitive sensing module 136. Without a power source 148, at least one of the individual components and/or functions of the capacitive sensing module 136 may be disabled and/or interrupted. In some aspects, a primary power source 148 is provided to power the capacitive sensing module 136 components, while upon disruption to received power, a secondary power source 148 may be utilized. For example, the capacitive sensing module may include a battery backup feature configured to maintain at least one of the features of the capacitive sensing module during a temporary withdrawal of power, such as utilizing a battery backup as a secondary power source 148.

An exemplary alerting component 150, such as the audible alarm 24 of FIG. 3, may be coupled to the capacitive sensing module 136, according to embodiments of the invention. The alerting component 150 may be any type of indicator and/or alert corresponding to an initiated response by the capacitive sensing module 136. For example, the alerting component 150 may be a light alarm, an audible alarm, a vibrating alert, and text messaging alert, an emailing alert, and the like. In one embodiment, a capacitive sensing module may include a wireless component configured to connect to the internet, such as creating a connection over WiFi. As such, an alerting component 150 may be configured to automatically deliver a particular triggered alert and/or message to a particular user via an internet connection. In further aspects, an internect connection, either wireless or wired, between the capacitive sensing module and a remote computing device may be used to provide a notice to a first user that a second user is accessing an area protected by a guard system.

In some aspects of the invention, a capacitive sensing module 136 may be accessed by multiple users. As such, the authentication component 152 may determine whether a particular user is authorized access within the guard system 62. In some aspects, the authentication component 152 may be used to assign user-specific access rights to one or more users of the guard system. The authentication component 152 may be used to apply one or more rules to the outputs generated and/or transmitted by the communication component 146. For example, based on identifying a particular user attempting to access the interior of a guard system, the communication component may be utilized to communicate with one or more features of the capacitive sensing module 136 to either enable or disable the charge component 138 and either deny or permit access. As such, database 154 may be used to store one or more items of information accessed by the capacitive sensing module 136, such as a look-up directory of users authorized to access the interior contents of the guard system.

In FIG. 11, a flow diagram 164 provides an example of capacitance monitoring utilizing an exemplary capacitive sensing module. At block 166, a change in capacitance is monitored, which may include receiving capacitance monitoring data from one or more guards or portions of guards (outer frames, protective grids, bolts, vertical posts, etc.) via the capacitive sensing module. At block 168, a change in capacitance is monitored with respect to a baseline level of noise, such as a minimal tolerated level of noise that does not trigger an indication of detection. For example, a change in capacitance monitored by the capacitive sensing module may result from a person attempting to open an assembled guard system. In other aspects, a monitored change in capacitance may result from a person in proximity to the assembled guard system that is not yet in contact with any of the guard panels.

In some embodiments, if the monitored capacitance has not changed by a threshold amount, an indication is generated to continue monitoring capacitance at block 170. In further aspects, if a change in capacitance has satisfied a threshold amount (e.g., is greater than a predetermined level of noise that the system experiences but does not trigger an indication of presence and/or contact), a determination may be made regarding the capacitance change characteristics at block 172. In one embodiment, one or more characteristics of a threshold change in capacitance (as determined at block 168) may be used to trigger an appropriate and/or corresponding response to such received indication of detection. For example, a capacitance change characteristic may include a combination of various different measurable indications associated with a received indication of capacitance that has satisfied a threshold amount of capacitance change, such as a duration of a detected change in capacitance, a timing of a detected change in capacitance, a combined indication of a user identity (e.g., via radio-frequency identification (RFID)) and attempted entry via an appropriate entry point (e.g., a door handle), and the like. In one embodiment, a duration of a capacitance change may be characterized at block 172 as being an instant change in capacitance (i.e., a touch by a user) and may further be characterized by a time of day when the instant change in capacitance is detected. As such, a user bumping into a capacitive feature of the guard system may signal a threshold change in capacitance (block 168) but may not necessarily prompt additional responses based on the associated time of day at block 172.

At block 174, a determination is made whether at least one of the capacitance change characteristics satisfies a detection threshold. If not, at block 180, the system continues monitoring capacitance. If the capacitance change characteristics determined at block 172 satisfy one or more detection thresholds at block 174, such as a duration/user identity/time of day detection threshold, the capacitance change is identified at block 176. In some embodiments, the identifying of a capacitance change based on one or more satisfied detection thresholds may include comparing a list of authorized users to the identity of the user (via RFID detection) that has come into contact with the capacitive component of the guard system. For example, an authenticated entry protocol may be established for particular users that are permitted to access an area enclosed by a guard coupled to a capacitive sensing module. Such protocol may utilize processing at the capacitive sensing module and/or at a remote computing device to determine when and whether a particular user, identified by RFID, is permitted access to a particular area enclosed by a monitored guard. 144

At block 178, a corresponding response is initiated for the identified capacitance change.

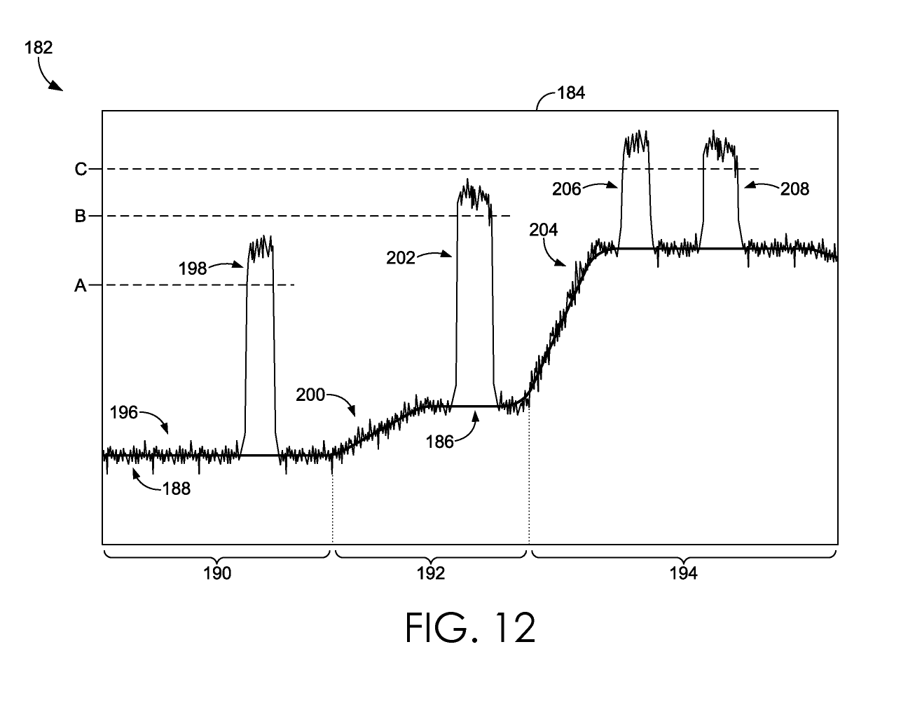

Referring finally to FIG. 12, exemplary capacitance detection 182 is shown, having a display 184, a baseline 186, and a capacitance measurement 188. Further, as measured along an x-axis over time, the display 184 also includes a first portion 190, a second portion 192, a third portion 194, a first non-detection portion 196, a first detection portion 198, a second non-detection portion 200, a second detection portion 202, a third non-detection portion 204, a third detection portion 206, and a fourth detection portion 208. In embodiments of the invention, capacitance measurement 188 may be monitored over time in comparison to a baseline 186. A minimal amount of change over time, such as that detected during the first portion 190 at the first non-detection portion 196, may provide an indication of noise inherent to the capacitive component and/or the capacitive sensing module that does not trigger a corresponding response. Subsequently, at first detection portion 198, a threshold change in capacitance is detected at or above a first threshold A, which may trigger a corresponding response (e.g., an alert, a warning buzzer, a text message to an authorized manager, etc.).

After the initial spike in detection at first detection portion 198, during second portion 192 of monitoring, a second non-detection portion 200 may correspond to a gradual change in baseline 186 and corresponding shift in a tolerated level of noise by the capacitance monitoring. As such, the second threshold B is adjusted to provide an adjusted threshold level of change in capacitance with respect to the first threshold A. Similarly, in third portion 194, a gradual increase in baseline 186 and corresponding capacitance measurement 188 may result in an altered threshold, such as the third threshold C, which both third detection portion 206 and fourth detection portion 208 satisfy. In further aspects, based on a level of capacitance measured within a portion of monitoring (i.e., within first, second, and third portions 190, 192, and 194), the adjusted threshold requirements correspond to one or more additional factors that alter the capacitance of the guard system but do not directly correlate to a particular detection event.

A variety of detection events may be monitored for and/or tracked by the capacitive sensing module. In one aspect, a detection event may include receiving an indication of human contact with the guard system for a particular duration of time. For example, a change in capacitance between about 20-24 picofarads may indicate that human contact has been detected by the capacitive sensing module of a guard system, while in some embodiments, a threshold change in capacitance of at least 22 picofarads may be required before an indication of human detection is determined. A change in capacitance that is longer in duration may indicate that a user is leaning against the guard system in one embodiment, while in further embodiments, an instant change in capacitance may indicate a user manipulating a portion of the cage and/or attempting entry. In further aspects, a detection event may include a triggering of one or more corresponding features of the guard system based on a capacitance change of a particular threshold level of capacitance, over a particular threshold amount of time, from a particular user (e.g., a non-authorized user), at a particular time of day, etc.

In further embodiments, one or more determinations may be made by the capacitive sensing module, such as the determinations made with respect to the monitoring component and detection component described above with respect to FIG. 9. In some aspects, the satisfying of a threshold and/or triggering of an alert may be communicated to one or more locations via the communication component. For example, a triggered indication of unauthorized access may be sent via text message to a supervisor in charge of maintaining the integrity of the guard system. In further aspects, a log may be stored to characterize usage patterns and/or access information to the guard, such as monitoring which users enter the interior of the guard system and for what duration of time. The capacitive sensing module, either by a computing device coupled to the capacitive sensing module or via a remote computing device receiving information from the capacitive sensing module, may utilize both capacitive detection data and RFID information to determine particular user access trends and/or patterns over time. In further aspects, from a security standpoint, capacitance detection data may be combined with RFID technology to determine an identity of a person accessing an interior of a guard system prior to alerting a response that the guard system has been compromised.

From the foregoing, it will be seen that this invention is one well adapted to attain all the ends and objects hereinabove set forth together with other advantages, which are obvious and which are inherent to the structure.

It will be understood that certain features and subcombinations are of utility and may be employed without reference to other features and subcombinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

1. A method for detecting presence with respect to a guard, the method comprising:
receiving information provided by at least one capacitive component associated with the guard;
determining that a change in voltage satisfies a threshold amount; and
based on determining that the threshold amount is satisfied, initiating a corresponding response.

2. The method of claim 1, wherein the at least one capacitive component is configured to have a voltage based on proximity of an object to the at least one capacitive component.

3. The method of claim 1, wherein the at least one capacitive component is directly coupled to at least a portion of the guard.

4. The method of claim 3, wherein the guard comprises:
(1) a plurality of guard panels, at least a portion of each of the plurality of guard panels comprising a conductive material; and
(2) a guard bottom comprising at least one base plate, wherein the at least one base plate is coupled to a non-conductive coaster, said non-conductive coaster positioned between the guard bottom and a floor surface.

5. The method of claim 1, wherein determining that a change in voltage satisfies a threshold amount comprises comparing an average voltage detected over a particular amount of time with the threshold amount.

6. The method of claim 5, wherein the threshold amount indicates that either 1) presence is detected in proximity to the guard; or 2) presence is no longer detected in proximity to the guard.

7. The method of claim 1, wherein initiating a corresponding response comprises:
activating at least one function associated with the guard based on a determination that presence is detected, or
activating at least one function associated with the guard based on a determination that presence is no longer detected in proximity to the guard.

8. A guard system for restricting access to an internal area using capacitance detection, the guard system comprising:
a guard enclosure comprising a plurality of guard panels coupled to a plurality of vertical posts; and
a capacitive sensing module coupled to one or more of the plurality of guard panels and the plurality of vertical posts, wherein the capacitive sensing module comprises:
(1) a charge component configured to apply a voltage to the guard enclosure,
(2) a monitoring component configured to monitor a change in capacitance with respect to the guard enclosure, and
(3) a detection component configured to determine whether a threshold level of change in capacitance is satisfied.

9. The guard system of claim 8, wherein the capacitive sensing module further comprises one or more of the following:
(1) a calibrating component;
(2) a communication component;
(3) a power source;
(4) an alerting component;
(5) an authentication component; and
(6) a database component.

10. The guard system of claim 8, wherein the capacitive sensing module is coupled to a remote computing device via a network, wherein the remote computing device is configured to perform one or more functions associated with one or more of the charge component, the monitoring component, and the detection component.

11. The guard system of claim 8, further comprising:
a non-conductive coaster coupled between each of the plurality of vertical posts and a ground surface.

12. The guard system of claim 9, wherein the communication component comprises one or more of a wired communication connection to a first external component and a wireless communication connection to a second external component.

13. The guard system of claim 9, wherein the power source comprises at least one primary power source and at least one secondary power source.

14. The guard system of claim 9, wherein the authentication component is configured to utilize RFID data in association with received capacitance monitoring data to determine whether a user is or is not permitted to access an internal portion of the guard enclosure.

15. The guard system of claim 9, wherein the calibrating component is configured to:
receive data collected by the monitoring component from at least a portion of one or more of the plurality of guards and the plurality of vertical posts; and
adjust a baseline capacitance corresponding to a noise floor to provide an adjusted threshold level of detection required to initiate a response.

16. A capacitive guard device for monitoring and restricting user access, the capacitive guard device comprising:
a capacitive guard comprising:
(1) a plurality of guard panels, each of the plurality of guard panels comprising a capacitive material, and
(2) a plurality of vertical posts coupled to the plurality of guard panels, wherein each of the plurality of vertical posts comprises a capacitive material; and further wherein each of the plurality of vertical posts is coupled to at least one of the plurality of guard panels along a vertical axis of the plurality of guard panels to provide an enclosed space within the capacitive guard that is inaccessible by a user adjacent the vertical axis; and
a capacitive sensing module coupled to at least a portion of one or more of the plurality of guard panels and the plurality of vertical posts, the capacitive sensing module comprising one or more of the following:
(1) a charge component;
(2) a monitoring component;
(3) a detection component;
(4) a charge component;
(5) a monitoring component;
(6) a detection component;
(7) a calibrating component;
(8) a communication component;
(9) a power source;
(10) an alerting component;
(11) an authentication component; and
(12) a database.

17. The capacitive guard device of claim 16, wherein each of the plurality of guard panels comprises at least one of:
a guard outer frame;
a guard protective grid;
a power cord;
a lead;
a warning light;
an audible alarm;
a vertical support post;
a non-conductive washer; and
a non-conductive coaster.

18. The capacitive guard device of claim 16, wherein the capacitive sensing module is coupled to one or more of the following:
an external wired component; and
am external wireless component.

19. The capacitive guard device of claim 16, wherein the capacitive sensing module is coupled via a wireless connection to a remote computing device configured to receive one or more items of monitoring data communicated to the remote computing device from the capacitive sensing module via the wireless connection.

20. The capacitive guard device of claim 19, wherein the one or more items of monitoring data are communicated via text message from the capacitive sensing module to another user on a wireless handheld device.
